(19) United States
(12) Patent Application Publication
(10) Pub. No.: US 2011/0120547 A1
(43) Pub. Date: May 26, 2011

(54) Photoelectric device

(75) Inventors: Chii-Wann Lin, Taipei (TW); Chien-Sheng Liu, Taipei (TW)

(73) Assignee: National Taiwan University, Taipei (TW)

(21) Appl. No.: 12/657,091

(22) Filed: Jan. 13, 2010

(30) Foreign Application Priority Data
Nov. 20, 2009 (TW) 98139449

(51) Int. Cl. H01L 31/00

(52) U.S. Cl. 136/256; 136/261

(57) ABSTRACT

The present invention provides a photoelectric device, including a photoelectric semiconductor thin film having a light facing surface and a back light surface; and a photoelectric converter having a medium and photoelectric converting particles mounted on the medium, wherein the photoelectric converter is disposed at an outer side of the light facing surface of the photoelectric semiconductor film for absorbing and converting solar energy so as to enhance photoelectric conversion efficacy. The photoelectric converter absorbs the wavelength that the photoelectric semiconductor thin film cannot absorb, and emits the frequency band that the photoelectric semiconductor thin film can absorb. Thus, the photoelectric device of the present invention decreases the interference of light absorption, increases the light emission, eliminates the wastes of incident light, and increases the photoelectric conversion efficacy. Hence, the fabrication method of the solar cell is simplified, and the cost is decreased in the present invention.

### BACKGROUND OF THE INVENTION

1. Field of the Invention

The present invention relates to a photoelectric device, and more particularly, to a photoelectric device having a photoelectric converter disposed at an outer side of a light facing side of a photoelectric semiconductor film to enhance the photoelectric conversion efficacy.

2. Description of Related Art

In response to the energy crisis and the greenhouse effect, it is noted and invested to develop the renewable energy, wherein it is a trend to develop the solar energy. A solar cell alternatively named as a photovoltaic cell refers to a photoelectrical semiconductor film for outputting electric power after absorbing solar energy. In order words, upon solar irradiation, the solar energy is transferred into the electric power by the solar cell. There are various solar cells, which generally include a silicon solar cell, a polycrystal silicon solar cell, an amorphous silicon solar cell, a dye-sensitized solar cell, a III-V compound semiconductor (such as GaAs, InP, InGaP) solar cell, a II-VI compound semiconductor (such as CdTe, CulnSe₂) solar cell, a CISe solar cell, a CIGSe solar cell, an organic solar cell, etc.

Currently, solar cells are developed via selecting the material such as dye particles for absorbing short wavelength energy, emitting long wavelength light and providing an intermediate layer for electron transfer, or via a structural change such as a design of quantum well for increasing the tunneling effect so as to increase photoelectric current.

Nowadays, in the solar energy industry, the photo/electric conversion efficacy is increased by changing the structure and the constitutions. However, due to properties of materials, the photo/electric conversion cannot be performed on full spectrum light. Taiwanese Patent No. 1241029 discloses a dye-sensitized solar cell including a working electrode, a couple of electrodes, and electrolytes between the working electrodes and the couple of electrodes, wherein the working electrode includes an electrically conductive substrate, a semiconductor nano film having a plurality of conductive particles, and a dye layer formed on the semiconductor nano film. The dye layer is formed by single or multiple layers of dye molecules absorbing on the surface of the semiconductor nano film, and thus the fabrication of the solar cell is complicated. Taiwanese Patent No. 1302753 discloses an amorphous solar cell, which includes a semiconductor layer having a semiconductor layer with a first type of conductivity, a semiconductor layer with a second type of conductivity and a semiconductor layer with a third type of conductivity, and includes a quantum dot structure formed between the semiconductor layer with the first type of conductivity and the semiconductor layer with the second type of conductivity. The first type of conductivity is opposite to the second type of conductivity. The quantum dot structure is formed by a metal layer via the heat treatment, wherein the metal layer is disposed between the semiconductor layer with the first type of conductivity and the semiconductor layer with the second type of conductivity. However, this fabrication method increases the steps and the cost of the solar cell. US Patent Application Publication No. 20080142075 discloses a photoelectric device or a solar cell having one or more photoelectric layers, wherein at least one photoelectric layer includes photoactive sub-layers of nanoparticles with different sizes, compositions or both. The photoactive sub-layer includes a nano complex film having three sub-layers of quantum dots and electron hole conductivity layers, such that the fabrication method of the solar cell is complicated and the cost is high. US Patent Application Publication No. 20080121271 discloses a photoelectric device including three or more solar cells which are layered on top of each other, at least one quantum dot incorporated in at least one of the solar cells which is between the other solar cells; a first conductor coupled to one of the solar cells; and a second conductor coupled to another one of the solar cells. This photoelectric device includes the quantum dot incorporated into the solar cell, such that the fabrication method is complicated and the cost is high.

The quantum dot is disposed in an intermediate layer or a semiconductor in current technology, resulting in the complicated fabrication and high cost. Further, the energy emitted to the quantum dot is interfered by the layers above or below the quantum dot. Hence, it is an urgent issue to simplify the fabrication, lower the cost, decrease the interference on the light absorbance and increase the light emission, so as to enhance the conversion efficacy of the solar cell.

### SUMMARY OF THE INVENTION

The present invention provides a photoelectric device. The photoelectric device includes a photoelectric semiconductor thin film having a light facing surface and a back light surface; and a photoelectric converter having a medium and photoelectric converting particles mounted on the medium, wherein the photoelectric converter is disposed at an outer side of the light facing surface of the photoelectric semiconductor thin film for absorbing and converting solar energy so as to enhance photoelectric conversion efficacy.

The quantum efficiency is the ratio of the light absorption to the produced electro holes. The photoelectric converter has the medium and the photoelectric converting particles mounted on the medium. Further, the photoelectric converter is disposed in the light facing surface of the solar cell, so as to efficiently converting the incident light, enhance the photoelectric conversion efficacy, and increase the output power in the present invention.

In addition, the photoelectric converter is disposed at the light facing surface of the solar cell for absorbing the wavelength that the solar cell cannot absorb and emitting the spectrum band that the solar cell can absorb, such that the photoelectric conversion efficacy in increased. Therefore, by using the photoelectric converter of the present invention, the fabrication method of the solar cell is simplified, the cost is lowered, the interference of light absorption is decreased, the incident light is increased, the waste of incident light is eliminated, and the photoelectric conversion efficacy is increased.

### BRIEF DESCRIPTION OF THE DRAWINGS

FIG. 1 is a diagram showing the current-voltage curves of Control Example 1 and Comparative Examples 1-2 according to the present invention;

FIG. 2 is a diagram showing the current-voltage curves of Comparative Example 1 and Example 1 according to the present invention;

FIG. 3 is a diagram showing the current-voltage curves of Comparative Example 2 and Example 2 according to the present invention; and

FIG. 4 is a diagram showing the current-voltage curves of Comparative Example 3 and Example 3 according to the present invention.

### DETAILED DESCRIPTION OF THE PREFERRED EMBODIMENTS

The detailed description of the present invention is illustrated by the following specific examples. Persons skilled in the art can conceive the other advantages and effects of the present invention based on the disclosure contained in the specification of the present invention.

The photoelectric device of the present invention includes a photoelectric semiconductor thin film having a light facing surface and a back light surface; and a photoelectric converter having a medium and photoelectric converting particles mounted on the medium, wherein the photoelectric converter is disposed at an outer side of the light facing surface of the photoelectric semiconductor thin film for absorbing and converting solar energy so as to enhance photoelectric conversion efficacy.

The photoelectric semiconductor thin film is a solar cell. The solar cell is a silicon semiconductor solar cell, a compound semiconductor solar cell, a dye-sensitized solar cell or an organic solar cell. The silicon semiconductor solar cell may be a crystalline silicon solar cell, a polycrystalline silicon solar cell or a non-crystalline silicon solar cell. The compound semiconductor solar cell may be a III-V compound semiconductor solar cell, a II-VI compound semiconductor solar cell, a CISe solar cell, a CIGSe solar cell and so on. The dye-sensitized solar cell includes an organic dye-sensitizing agent (such as polypyridyl ruthenium bound with carboxylic acid, polypyridyl ruthenium bound with phosphoric acid, polynuclear polypyridyl ruthenium and etc.) or an in organic dye (such as CdS, CdSe, FeS₂, RuS₂ and etc.) The organic solar cell includes an organic material, which is similar to a plastic material.

The medium of the present invention may be a chitosan, a hydrogel, a silica gel, or other polymers being transparent upon solidification. In one embodiment, the medium is a chitosan. The photoelectric converting particles of the present invention are quantum dots made of one selected from the group consisting of ZnSe, CdSe, CdS, HgS, ZnO, ZnS, SnS, ZnTe, CdTe, and a combination thereof. In the photoelectric converter, the weight ratio of the medium to the photoelectric converting particles depends upon the size, material and properties of the solar cell. In one embodiment, the average diameter of the photoelectric converting particles is in a range from 5 to 100 micrometers, preferably in a range from 5 to 80 micrometers, and more preferably in a range from 5 to 50 micrometers for absorbing and emitting the wavelength in need.

The photoelectric converter of the present invention may have a surface with regular or irregular arrangement of protrusions. The output voltage, current and irradiation conditions of the solar cell are associated with working points of the load. Thus, the photoelectric converter has the surface with protrusions for increasing the surface area, so as to increase the irradiation area and incident light. Therefore, the solar cell has better photoelectric converting efficacy. Generally, the thickness of the photoelectric converter is in a range from 10 to 1000 micrometers, and preferably in a range from 20 to 100 micrometers.

In the photoelectric converter of the present invention, the photoelectric converting particles mounted on the medium are excited under UV irradiation or electron excitation, so as to obtain a spectrum in a range from 250 to 800 nm or a white light source. In an embodiment, the photoelectric converting particles mounted on the medium are excited under UV irradiation or electron excitation, so as to obtain a spectrum in a range from 400 to 700 nm or a white light source. Preferably, the UV light is converted into the yellow-green light by the photoelectric converter of the present invention.

The photoelectric converter may be cut into various shapes to be attached to the light facing surface of the solar cell. The quantum dots of the photoelectric converter provide additional energy level, enhance the light absorption efficiency of various wavelengths, significantly inhibit the energy release while carriers irradiate phonons at energy levels, increase the impact ionization of carriers, produce additional electron-hole pairs, and efficiently increases the photoelectric current of the solar cell. Therefore, the solar cell has high efficacy due to the photoelectric converter disposed at the light facing surface of the solar cell. In one embodiment, the photoelectric conversion efficacy is increased by the photoelectric converter for at least 25% under UV irradiation; and the photoelectric conversion efficacy is increased by the photoelectric converter for at least 1.2% under irradiation of a white light source.

Hence, due to the photoelectric semiconductor thin film, the conversion efficacy of the solar cell is improved. In the present invention, the wavelength that the solar cell cannot absorb is converted by the photoelectric converter into the wavelength that the solar cell can absorb, such that the interference on the light absorption is decreased, the incident light is increased, the waste of the incident light source is decreased, and the photoelectric conversion efficacy is enhanced.

The advantages and effects of the present invention are illustrated in the following examples. The scope of the present invention is not limited by the examples.

Preparation 1

The gel was prepared by phase inversion, and added with chitosan dissolved in formic acid. The mixture was stirred to form a gel medium having the continuous phase of high molecular weight molecules. The photoelectric converting particles were quantum dots (Qdot 565 ITK Carboxyl quantum dots @ 8 μm purchased from Invitrogen).

The periodic structures of wells were formed on a glass substrate via photoresist processing by MEM, wherein the period was 20 micrometers. The chitosan gel medium was completely mixed with the photoelectric converting particles (Qd565). The mixture was added into the wells of the glass substrate and covered with the gel medium. The mixture then stood for 24 hours to be dried and solidified, so as to obtain Sample 1 of the photoelectric converter having the surface with protrusions.

Preparation 2

The steps of Preparation 1 were repeated except forming periodic structures of wells on a glass substrate, so as to obtain Sample 2 of the photoelectric converter having surfaces with no protrusions.

### CONTROL EXAMPLE 1

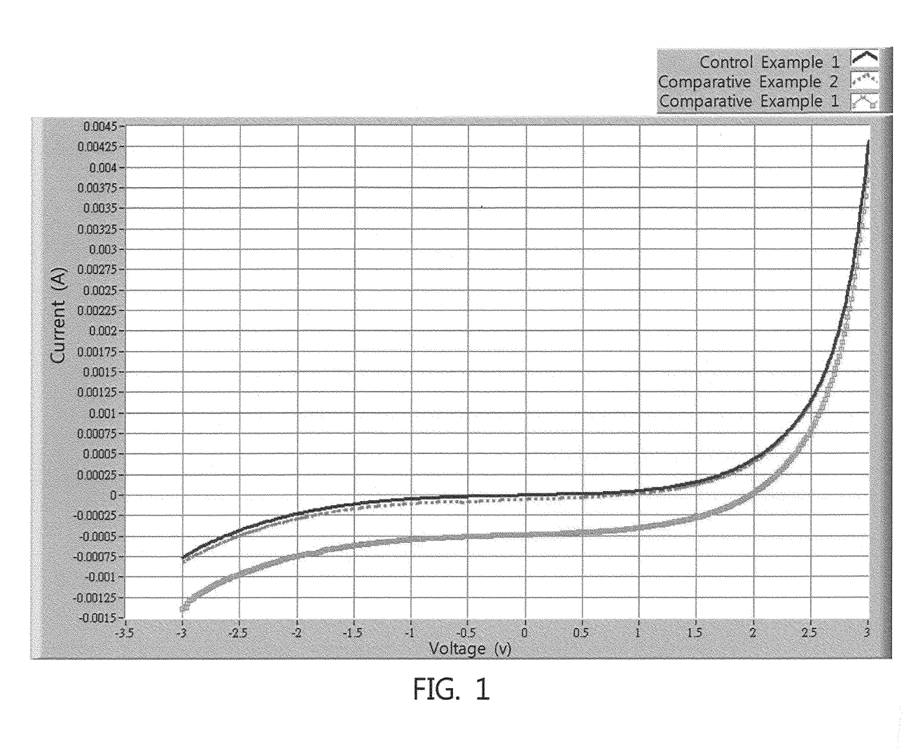

The solar cell without the photoelectric converter was placed in a black box to eliminate the environmental factors. As shown in Table 1, under no irradiation, the current and voltage of the solar cell were measured by the source meter, and the conversion power was calculated. The current-voltage curve was shown in FIG. 1. The conversion power was the maximal absolute value of the current value multiplied by the voltage value at each working point in the region of the current-voltage curve, wherein the voltage is above zero and the current is below zero.

### COMPARATIVE EXAMPLES 1-2

The solar cell without the photoelectric converter was placed in a black box to eliminate the environmental factors. As shown in Table 1, under the white light ad UV irradiation, respectively, the current and voltage of the solar cell were measured by the source meter at different wavelengths, and the conversion power was calculated. The current-voltage curve was shown in FIG. 1. The conversion power was the maximal absolute value of the current value multiplied by the voltage value at each working point in the region of the current-voltage curve, wherein the voltage is above zero and the current is below zero.

### EXAMPLE 1

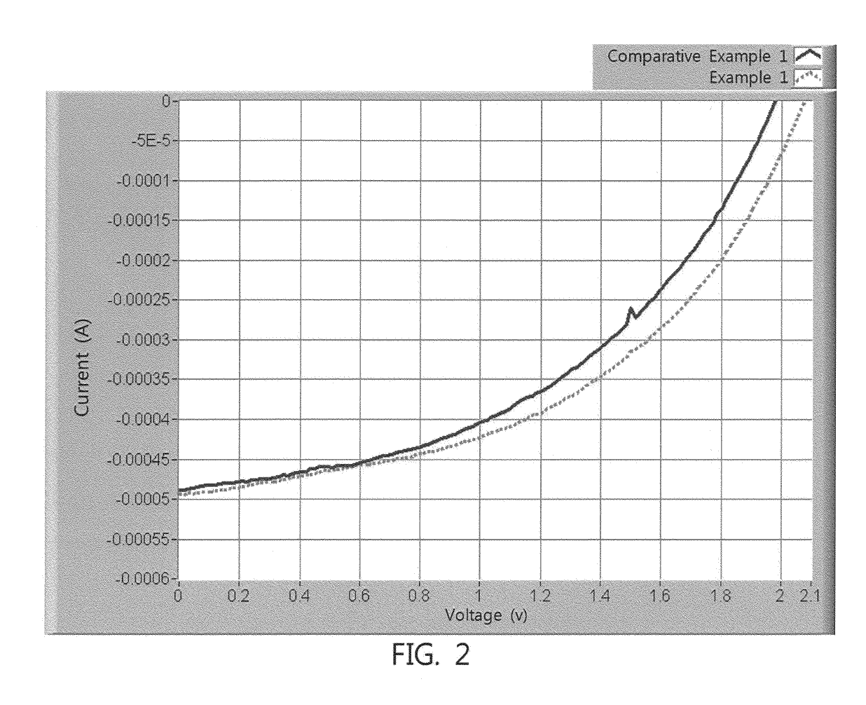

The solar cell was cover with Sample 1 of the photoelectric converter, and placed in a black box to eliminate the environmental factors. As shown in Table 1, under the white light irradiation, the current and voltage of the solar cell were measured by the source meter at different wavelengths, and the conversion power was calculated. The current-voltage curve was shown in FIG. 2. The conversion power was the maximal absolute value of the current value multiplied by the voltage value at each working point in the region of the current-voltage curve, wherein the voltage is above zero and the current is below zero.

### EXAMPLE 2

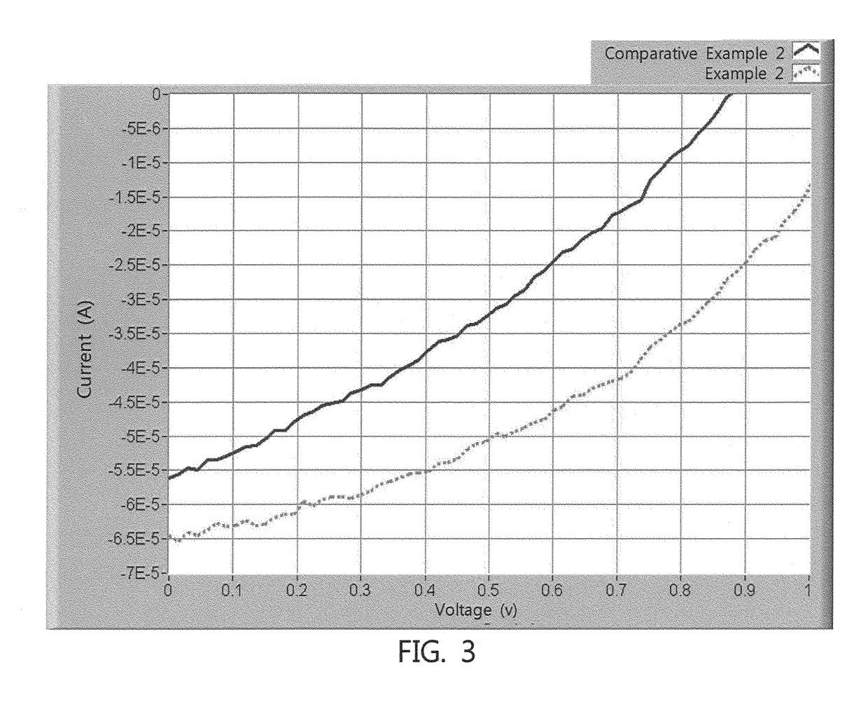

The solar cell was cover with Sample 1 of the photoelectric converter, and placed in a black box to eliminate the environmental factors. As shown in Table 1, under UV irradiation, the current and voltage of the solar cell were measured by the source meter at different wavelengths, and the conversion power was calculated. The current-voltage curve was shown in FIG. 3. The conversion power was the maximal absolute value of the current value multiplied by the voltage value at each working point in the region of the current-voltage curve, wherein the voltage is above zero and the current is below zero.

TABLE 1

| | | Voltage | Current | Power |
|---|---|---|---|---|
| | Irradiation | (V) | (μA) | (μW) |
| Control Example 1 | none | 0.105 | −3.66 | 0.38 |
| Comparative Example 1 | White light | 1.24 | −354.1 | 441.24 |
| Comparative Example 2 | UV | 0.56 | −36.9 | 20.5 |
| Example 1 | White light | 1.39 | −358.7 | 500 |
| Example 2 | UV | 0.65 | −45.48 | 30 |

The photoelectric conversion power was determined based on the current-voltage curve. As shown in Table 1, the conversion power in Control Example I was 0.38 μW, the conversion power under the white light irradiation in Example 1 was 500 μW, and the conversion power under the UV irradiation in Example 2 was 30 μW. Accordingly, the UV light can be absorbed and converted by the photoelectric converter of the present invention.

### COMPARATIVE EXAMPLE 3

The steps in Comparative Example 1 were repeated. As shown in Table 2, under UV irradiation, the current and voltage of the solar cell were measured by the source meter at different wavelengths, and the conversion power was calculated.

### EXAMPLE 3

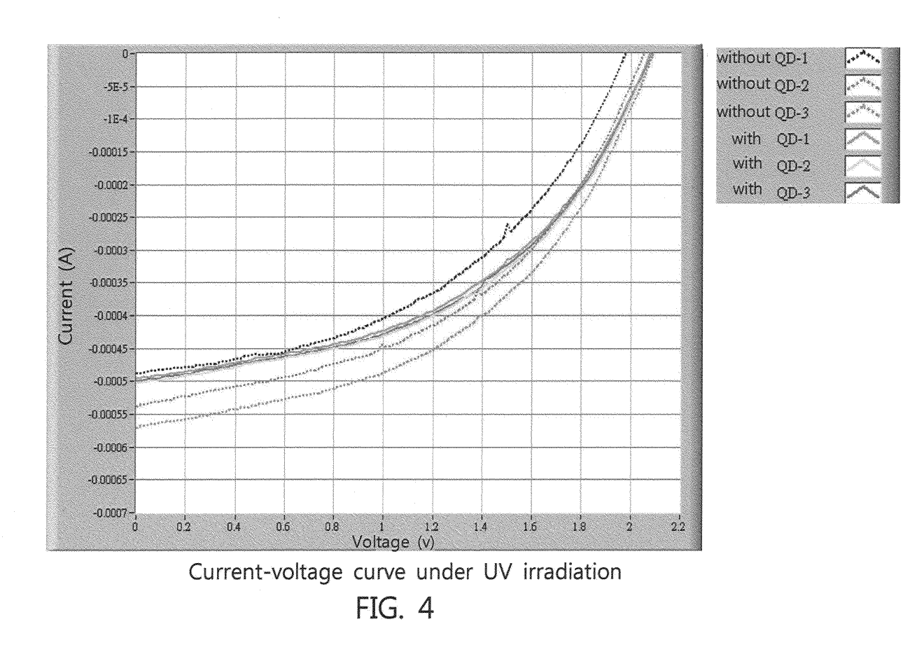

The solar cell was cover with Sample 2 of the photoelectric converter, and placed in a black box to eliminate the environmental factors. As shown in Table 2, under UV irradiation, the current and voltage of the solar cell were measured by the source meter at different wavelengths, and the conversion power was calculated. The current-voltage curve was shown in FIG. 4. In comparison with Comparative Example 3, the UV light can be absorbed and converted by the photoelectric converter of the present invention.

TABLE2

| | Voltage | Current | Power |
|---|---|---|---|
| | (V) | (μA) | (μW) |
| Comparative Example 3 | 0.56 | −36.9 | 20.5 |
| Example 3 | 0.66 | −43.96 | 29 |

As shown in Table 2, the solar cell without the photoelectric converter had −36.9 μA of the photoelectric current density, 0.56 V of voltage and 20.5 μW of the conversion power. The solar cell with the photoelectric converter of the present invention had −43.96 μA of the photoelectric current density, 0.66 V of voltage and 29 μW of the conversion power. It is clear that the photoelectric converter of the present invention enhances the conversion efficiency of the solar cell.

In light of the above illustration, there is no need to change the design of the solar cell, the photoelectric converter is disposed at the light facing surface of the solar cell, so as to simplify the fabrication method of the solar cell and also lower the cost. Furthermore, the photoelectric converter of the present invention enhances the conversion efficacy of the solar cell for at least 25%. Hence, the photoelectric converter of the present invention decreases the interference on the light absorption, and increases the incident light, such that the solar cell has high conversion efficacy.

The invention has been described using exemplary preferred embodiments. However, it is to be understood that the scope of the invention is not limited to the disclosed arrangements. The scope of the claims, therefore, should be accorded the broadest interpretation, so as to encompass all such modifications and similar arrangements.

1. A photoelectric device, comprising:
a photoelectric semiconductor thin film having a light facing surface and a back light surface; and
a photoelectric converter having a medium and photoelectric converting particles mounted on the medium,
wherein the photoelectric converter is disposed at an outer side of the light facing surface of the photoelectric semiconductor thin film for absorbing and converting solar energy so as to enhance photoelectric conversion efficacy.

2. The photoelectric device of claim 1, wherein the photoelectric semiconductor thin film is a solar cell.

3. The photoelectric device of claim 2, wherein the solar cell is a silicon semiconductor solar cell, a compound semiconductor solar cell, a dye-sensitized solar cell or an organic solar cell.

4. The photoelectric device of claim 3, wherein the silicon semiconductor solar cell is a crystalline silicon solar cell, a polycrystalline silicon solar cell or a non-crystalline silicon solar cell.

5. The photoelectric device of claim 3, wherein the compound semiconductor solar cell is a III-V compound semiconductor solar cell, a II-VI compound semiconductor solar cell, a CISe solar cell or a CIGSe solar cell.

6. The photoelectric device of claim 1, wherein the medium is a chitosan, a hydrogel, a silica gel, or other polymers being transparent upon solidification.

7. The photoelectric device of claim 1, wherein the photoelectric converting particles are quantum dots.

8. The photoelectric device of claim 7, wherein the quantum dots are made of one selected from the group consisting of ZnSe, CdSe, CdS, HgS, ZnO, ZnS, SnS, ZnTe, CdTe, and a combination thereof.

9. The photoelectric device of claim 1, wherein the photoelectric converter has a surface with protrusions.

10. The photoelectric device of claim 1, wherein the photoelectric converting particles have an average diameter ranging from 5 to 100 micrometers.

11. The photoelectric device of claim 1, wherein the photoelectric converting particles have a thickness ranging from 10 to 1000 micrometers.

12. The photoelectric device of claim 1, wherein the photoelectric converter obtains a spectrum from 250 to 800 nm or a white light source under UV excitation or electron excitation.

13. The photoelectric device of claim 1, wherein the photoelectric converter obtains a spectrum from 400 to 700 nm or a white light source under UV excitation or electron excitation.

14. The photoelectric device of claim 1, wherein the photoelectric conversion efficacy is increased by the photoelectric converter for at least 25% under UV irradiation.

15. The photoelectric device of claim 9, wherein the photoelectric conversion efficacy is increased by the photoelectric converter for at least 1.2% under irradiation of a white light source.
